(19) United States
(12) Patent Application Publication
(10) Pub. No.: US 2021/0200079 A1
(43) Pub. Date: Jul. 1, 2021

(54) NEGATIVE REFRACTION IMAGING LITHOGRAPHIC METHOD AND EQUIPMENT

(71) Applicant: The Institute of Optics and Electronics, The Chinese Academy of Sciences, Chengdu, Sichuan (CN)

(72) Inventors: Xiangang LUO, Chengdu, Sichuan (CN); Yanqin WANG, Chengdu, Sichuan (CN); Changtao WANG, Chengdu, Sichuan (CN); Ling LIU, Chengdu, Sichuan (CN); Weijie KONG, Chengdu, Sichuan (CN); Ping GAO, Chengdu, Sichuan (CN)

(73) Assignee: The Institute of Optics and Electronics, The Chinese Academy of Sciences, Chengdu, Sichuan (CN)

(21) Appl. No.: 16/771,784

(22) PCT Filed: Sep. 20, 2018
(86) PCT No.: PCT/CN2018/106685

§ 371 Date: Jun. 11, 2020

(30) Foreign Application Priority Data
Dec. 11, 2017 (CN) 201711323769.7

(51) Int. Cl. G03F 1/38; G03F 7/00; G03F 7/20

(52) U.S. Cl. CPC G03F 1/38; G03F 7/70425; G03F 7/001

(57) ABSTRACT

The embodiments of the present disclosure propose a negative refraction imaging lithographic method and equipment. The lithographic method includes: coating photoresist on a device substrate; fabricating a negative refraction imaging structure, wherein the negative refraction imaging structure exhibits optical negative refraction in response to beam emitted by exposure source; pressing a mask to be close to the negative refraction imaging structure; disposing the mask and the negative refraction imaging structure above the device substrate at a projection distance; and light emitted by the exposure source passes through the mask, the negative refraction imaging structure, the projection gap and is sequentially projected onto the photoresist for exposure.

### CROSS-REFERENCE TO RELATED APPLICATION(S)

This application is a National Stage Application of PCT/CN2018/106685, filed on Sep. 20, 2018, which claims priority to the Chinese Patent Application No. 201711323769.7, filed on Dec. 11, 2017, entitled “NEGATIVE REFRACTION IMAGING LITHOGRAPHIC METHOD AND EUQIPMENT”, and which applications are incorporated herein by reference in their entireties. A claim of priority is made to each of the above disclosed application.

### TECHNICAL FIELD

The present disclosure relates to the field of lithography, and more particularly, to a nano-imaging lithographic method and equipment which achieves a large area and a low cost, and in particular, to a negative refraction imaging lithographic method and equipment.

### BACKGROUND

Optical lithography is one of the important technical approaches for micro-nano manufacturing, and is widely applied in fields such as integrated circuits, optoelectronic devices, new material manufacturing, biomedicine etc. A resolution of a projection lithographic equipment depends on a numerical aperture NA of a projection objective and a wavelength of a light source. In order to realize high-resolution lithography, a numerical aperture of a projection objective of a conventional lithographic equipment is getting higher and higher. Currently, NA has exceeded 1, and may further achieve 1.4 if an immersion objective is used. However, a projection objective having a high numerical aperture involves twenty or thirty lenses, and shape accuracy and positioning accuracy of each lens need to be controlled on an order of nanometers (Tomoyuki, Matsuyama, The lithographic lens: its history and evolution, Proc. of SPIE, 6145:615403, 2006; Zeiss Corporation. Zeiss Homepage. http://www.zeiss.com, 2017). Therefore, the processing and detection technology of the entire projection objective is very complicated, which results in an increasing price of conventional high-resolution projection lithographic equipment (for example, a stepper and a scanner of photo lithography), with a single equipment costing tens of millions to hundreds of millions of dollars. Also due to technical complexity and cost issues, the conventional projection lithography may currently achieve a small field of view, and commercial lithographic machines generally have a fixed field of view which is 26 mm*33 mm. The cost may further be increased if stitching processing is used, which makes it difficult to meet requirements for processing of nano-devices such as integrated circuits, optoelectronics etc. with a larger area.

### SUMMARY

To this end, the present disclosure proposes a lithographic method and equipment based on a negative refraction imaging structure.

The negative refraction imaging lithographic method and equipment according to the embodiments of the present disclosure achieve an imaging lens effect with a high numerical aperture and a nano-scale resolution using a multilayer structured film material, and may project and image a pattern of a mask onto photoresist which is at a distance of more than several hundred nanometers to micrometers away, so as to achieve exposure and development of the photoresist.

According to an aspect of the present disclosure, there is proposed a negative refraction imaging lithographic method, comprising: coating photoresist on a device substrate; fabricating a negative refraction imaging structure on a mask, wherein the negative refraction imaging structure exhibits a negative refraction effect in response to a wavelength of light emitted by an exposure source; disposing the mask and the negative refraction imaging structure above the device substrate at a projection distance equal to a projection gap away from the device substrate; and emitting, by the exposure source, light, and sequentially projecting the light onto the photoresist for exposure through the mask, the negative refraction imaging structure, and the projection gap.

According to another aspect of the present disclosure, there is further proposed a negative refraction imaging lithographic equipment, comprising: an exposure source, an illumination system, an imaging lithographic objective lens, substrate leveling system, a working distance detection and control system, an alignment and positioning system, an air dust monitoring and purification systems ect. The imagaing lithographic objective lens is configured to and a negative refraction imaging structure, wherein the negative refraction imaging structure exhibits a negative refraction effect for a wavelength of light emitted by the exposure source; and the working distance detection and control system separates the imaging lithographic lens and the device substrate by a projection distance equal to a projection gap, wherein light emitted by the exposure source passes through the imaging lithographic objective lens and the projection gap and is sequentially projected onto the photoresist for exposure.

In order to solve the technical complexity of the projection lithographic objective while improving the resolution, the present disclosure applies an imaging structure having a negative refraction effect as a lithographic objective to the field of lithography to form a novel negative refraction imaging lithographic method, and develop a negative refraction imaging lithographic equipment based on the negative refraction imaging lithographic method. Since the negative refraction imaging structure has the characteristics of imaging without an optical axis, the lithographic objective composed of the negative refraction imaging structure may achieve point-to-point large-area perfect imaging without using a phase compensation method for the conventional projection lithographic objective. Compared with the conventional projection lithographic lens, the negative refraction imaging lithographic objective involved in the negative refraction imaging lithographic method and equipment has much lower requirements for a surface flatness and a position precision of lenses, and therefore the cost of the development of the imaging lithographic lenses may be reduced, thereby reducing the price of the lithographic equipment having a high resolution and a large-area lithography capability. In combination with surface processing precision and size of planar negative refraction imaging structure, the negative refraction imaging lithographic method and equipment may realize lithography with an imaging field size of more than 100 mm², and a projection imaging working distance (image distance) may be in an order of several hundreds of nanometers to micrometers, so as to achieve operations such as high-precision alignment, positioning and overlay processing of multilayered nanostructures etc.

In the present disclosure, the negative refraction imaging lithographic method and equipment are based on different optical transfer functions of the negative refraction imaging structure, and high-resolution grayscale lithography may be achieved through a single exposure, which is used for processing of a multi-step or continuous surface shape pattern, obtaining sub-wavelength diffractive optical elements (S.E.Bihndiek, Grayscale-to-color: scalable fabrication of custom multispectral filter arrays, ACS Photonics, 6(21), 3132-3141, 2019), a lens array (Qiang Li, Jaeyoun Kim, Curvature-controlled fabrication of polymer nanolens array, OSA 2019), etc., and are widely used in fields such as optical sensing, optical communication, medical treatment etc. However, the conventional projection lithography may only adopt multiple times precise alignment and overlay to meet the different requirements of the depth of patterns of the structure, which not only has high lithography cost but also has great technical difficulty. At the same time, a curved negative refraction imaging structure may be fabricated in combination with a curved mask base, which may reduce the requirements of control precision of alignment and overprinting while achieving demagnification imaging lithography as the conventional projection lithography.

Compared with another metalens Superlens, the negative refraction imaging lithographic method and equipment according to the present disclosure are different and have advantages. Superlens needs to amplify an evanescent wave and excite a Surface Plasmons (SP) mode, which results in that a working distance between Superlens and an image plane in photoresist is much shorter than a wavelength, a focal depth is also much less than the wavelength, the lithographic pattern has a shallow depth, the contrast is low, and it is difficult to control the working distance and realize large-area uniform lithography under conditions of existing processing precision for the mask and a surface flatness of a silicon wafer. The negative refraction imaging lithographic method and equipment according to the present disclosure adopt the effective negative refraction effect to realize sub-wavelength resolution negative refraction imaging, and project the pattern of the mask onto the surface of the photoresist, and the working distance and the focal depth may be extended to an order of the wavelength (several hundreds of nanometers to micrometers), which may realize large-area (more than 100 mm²) uniform working distance control and large-area pattern imaging lithography under conditions of the existing control precision of the nanometer distance detection and processing accuracy of the surface flatness of the mask substrate (less than 1/20 of the wavelength, i.e., on an order of 20-30 nm), while satisfying the needs of high aspect ratio lithography. At the same time, this method may also achieve an effect of processing of continuous surface micro-nano structure lithography.

### BRIEF DESCRIPTION OF THE DRAWINGS

FIG. 1 illustrates a flowchart of a negative refraction imaging lithographic method according to an embodiment of the present disclosure.

FIG. 2 illustrates a schematic structural diagram of a negative refraction imaging lithographic equipment according to an embodiment of the present disclosure.

FIG. 3 illustrates a schematic diagram of a negative refraction imaging process.

FIG. 4 illustrates a specific structural diagram of a negative refraction imaging lithographic method.

FIG. 5 illustrates a schematic diagram of a curved negative refraction imaging structure.

FIG. 6 illustrates a specific structural diagram of the negative refraction imaging lithographic equipment 200 shown in FIG. 2.

FIG. 7 illustrates a schematic diagram of grayscale lithography.

FIG. 8 illustrates a schematic diagram of two-dimensional pattern imaging lithography implemented by using a negative refraction imaging lithographic method and equipment according to an embodiment of the present disclosure.

FIG. 9 illustrates schematic diagram of two-dimensional pattern imaging lithography implemented by using a negative refraction imaging lithographic method and equipment according to an another embodiment of the present disclosure.

FIG. 10 illustrates simulation and experimental results of one-dimensional periodic grating pattern obtained by using the negative refraction imaging lithographic method and equipment according to other embodiment of the present disclosure.

### REFERENCE SIGNS

1 Illumination light beam
2 Mask
3 Negative refraction imaging structure
4 Material with a positive dielectric constant
5 Material with a negative dielectric constant
6 Transmitted light wave
7 Unexposed photoresist
8 Imaging device substrate
9 Exposed photoresist
10 Imaging lithographic lens
11 Pattern input layer
12 Imaging output layer
13 Protective layer
14 Protective pane
15 Exposure source
16 Substrate leveling and gap control system
17 Working distance detection system
18 Vibration isolation platform
19 Stage
20 Imaging substrate
21 Alignment and positioning system
22 Clean box or vacuum box
23 Grayscale mask
24 Imaging field with nonuniform intensity
25 Mask with a vertical part of a two-dimensional pattern
26 Mask with a horizontal part of a two-dimensional pattern
27 Two-dimensional pattern
28 Two-dimensional polyline mask pattern
29 One-dimensional grating correction pattern in a two-dimensional polyline mask

### DETAILED DESCRIPTION

Reference will now be made in detail to the embodiments of the present disclosure, examples of which are illustrated in the accompanying drawings, wherein the same numerals in the accompanying drawings all represent the same elements. Hereinafter, the embodiments of the present disclosure will be described in detail with reference to the accompanying drawings.

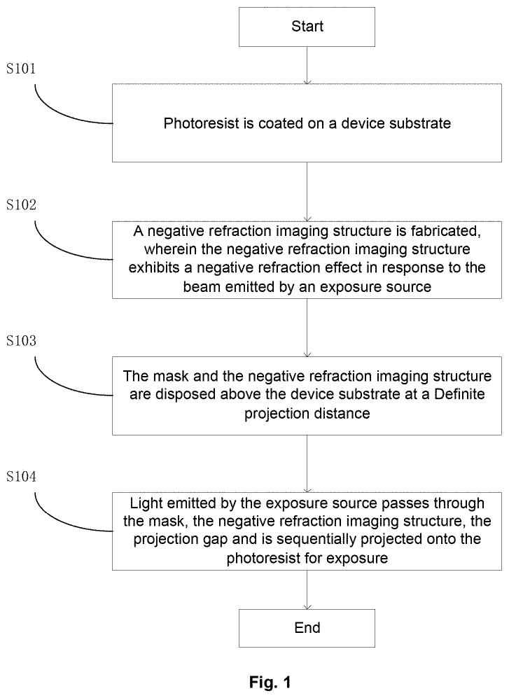

FIG. 1 illustrates a flowchart of a negative refraction imaging lithographic method according to an embodiment of the present disclosure. As shown in FIG. 1, the negative refraction imaging lithographic method comprises: coating photoresist on a device substrate (S101), fabricating a negative refraction imaging structure on a mask, wherein the negative refraction imaging structure exhibits a negative refraction effect in response to the beam emitted by an exposure source (S102); disposing the mask and the negative refraction imaging structure above the device substrate at a definite projection distance (S103): and light emitted by the exposure source passes through the mask, the negative refraction imaging structure, the projection gap and is sequentially projected onto the photoresist for exposure (S104). The negative refraction imaging structure comprises planar and curved structures, wherein the curved negative refraction imaging structure may achieve demagnification imaging.

FIG. 2 illustrates a schematic structural diagram of a negative refraction imaging lithographic equipment according to an embodiment of the present disclosure. As shown in FIG. 2, the negative refraction imaging lithographic equipment (200) comprises: an exposure source (201); a photoresist coating apparatus (202) configured to coat photoresist (7) on a device substrate (8); a planarized mask and a negative refraction imaging structure fabricated on the mask (3), wherein the negative refraction imaging structure (3) exhibits a negative refraction effect in response to beam emitted by the exposure source; an exposure gap control apparatus (204) configured to dispose the mask (2) and the negative refraction imaging structure (3) above the device substrate (8) at a definite projection working distance for exposure, wherein light emitted by the exposure source (1) passes through the mask (2), the negative refraction imaging structure (3), and the projection gap and is sequentially projected onto the photoresist (7) for exposure.

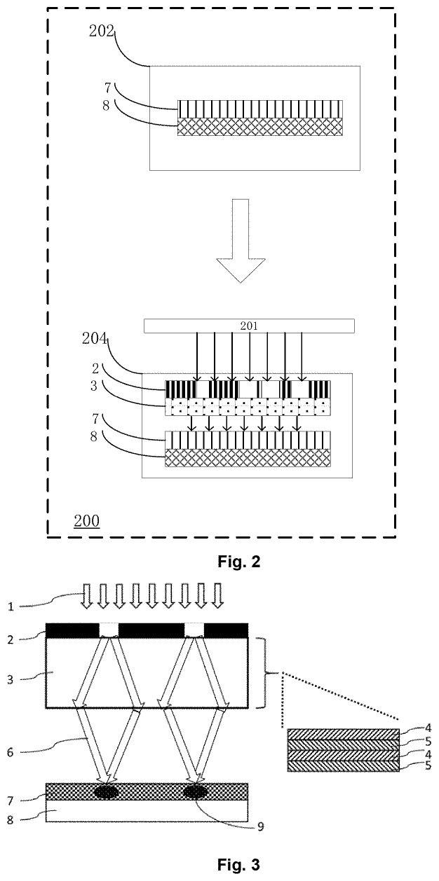

FIG. 3 illustrates a schematic structural diagram of a negative refraction imaging process. As shown in FIG. 3, an illumination beam (1) is transmitted in the negative refraction structure (3) through the mask (2), and is finally focused and imaged in the photoresist (7) coated on the imaging substrate (8). As shown in an illustration on the right side of FIG. 3, the negative refraction imaging structure may be formed by alternately stacking a material (4) with a positive permittivity and a material (5) with a negative permittivity.

The negative refraction imaging structure exhibits the negative refraction optical behavior, comprising a multilayered negative refraction imaging structure, and a complex negative refraction imaging structure. The complex negative refraction imaging structure may construct a polarization-independent effective negative refraction index material, so that the permittivity (ε) and the permeability (μ) are negative, for example, a hole-array multilayered negative refraction imaging structure, a three-dimensional negative refraction imaging structure ect. When the negative refraction imaging structure is described as an anisotropic material, the real part of effective permittivity lateral component has an opposite sign to that of—effective permittivity longitudinal component wherein for a multilayer structure composed of metal and dielectric layers, the lateral component of effective permittivity is ε_{//}=f·ε_{d}+(1−f)·εₘ, while the longitudinal component of that is ε_{//}=f·ε_{d}+(1−f)·εₘ, wherein ε_{//·//}>0 and ε_{⊥}<0 so that the multilayered structure exhibits negative refraction, where ε_{d} and εₘ are permittivities of the dielectric and the metal materials in the composite structure, respectively, and f=d_{d}/(d_{d}+dₘ) is a thickness duty ratio of a dielecric layer, where d_{d} and dₘ are thickness of the dielectric layer and the metal layer, respectively.

The multilayer negative refraction imaging structure is formed by alternately stacking two or more kinds of layers with different permittivities, and layers thickness satisfies the condition of negative refraction imaging, and exhibits a negative refraction effect. Under the condition of negative refraction, the multilayers could be periodical alternant structure, or aperiodic structure obtained by optimization algorithm to improve resolution, focal depth and utilization efficiency for energy of the negative refraction imaging. In order to realize a negative refraction, the real part of permittivity of at least one kind of material needs to be negative, and imaginary part of permittivity determining the loss needs to meet requirements of energy efficiency. The material with negative real part permittivity comprises, but not limited to, gold, silver, and aluminum. A two-dimensional hole array structure is introduced into the material with negative real part of permittivity to modulate effective permittivity and loss to realize negative refraction imaging, so as to form the hole-array multilayered negative refraction imaging structure, in order to obtain suitable permittivity and loss coefficient in deep ultraviolet, near infrared, infrared etc. The three-dimensional negative refraction imaging structure is a three-dimensional metamaterial structure with a negative refraction index. The negative refraction imaging lithographic structure in a form of three-dimensional complex structure may realize negative refraction imaging which is independent of Transverse Electric (TE) and Transverse Magnetic (TM) polarization states and has no polarization aberration, for example, a three-dimensional metamaterial structural unit having a negative effective refraction index (ε<0 and μ<0). By taking this unit as a basic structure, a three-dimensional negative refraction imaging structure which could realize a fixed negative refraction index distribution and a variable negative refraction index distribution may be designed. In order to prevent light fields with different polarization states from affecting imaging performance for complex two-dimensional patterns, the mask pattern for once exposure thereof is mostly the dense lines arranged in the same direction. The illumination light of which the electric field is polarized perpendicularly to the direction of the lines is selected, especially for the pattern with small critical dimension. In addition, high-resolution two-dimensional complex patterns may be achieved by stitching two or more lithographic processes of different one-dimensional mask patterns in different directions under polarized illumination in the respective directions. Pattern optimization methods such as proximity effect correction, phase shift mask etc. may be used to improve the fidelity of negative refraction imaging.

By selecting the film material and the corresponding thickness, or even filling liquid between the negative refraction imaging structure and the substrate of the lithographic device, the numerical aperture of the negative refraction imaging structure may be increased, thereby improving the imaging lithographic resolution.

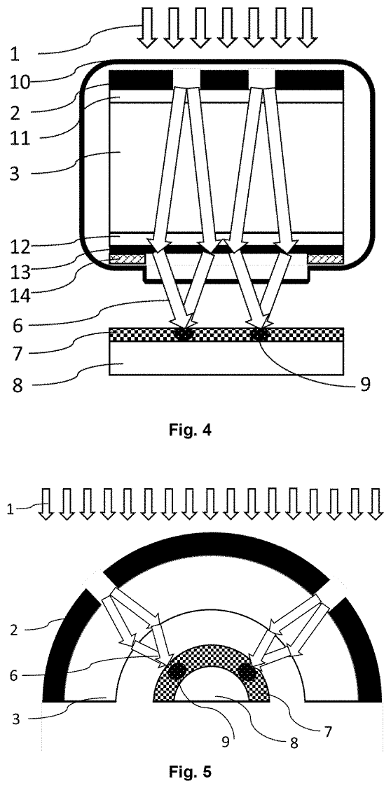

FIG. 4 illustrates a specific structural diagram of a negative refraction imaging lithographic method. As shown in FIG. 4, the negative refraction imaging lens (10) is composed of components such as a mask (2), pattern input layers (11), a negative refraction imaging structure (3), imaging output layers (12), a protective layer (13), a protective pane (14) etc.

Specifically, the negative refraction imaging structure further comprises pattern input layers on opposite sides, which planarizes the pattern layer of the mask. The material of the pattern input layers is transparent, and has high refraction index and low loss, the pattern input layers thickness is optimized to be matched with parameters of the negative refraction imaging structure. Impendence matching may be realized between the pattern input layers (impendence is Zᵢₙ(μ₁/ε₁)^{1/2}) and the negative refraction imaging structure (impendence is Zₗₑₙₛ=(μ/ε)^{1/2}), i.e., Zᵢₙ=Zₗₑₙₛ (μ and ε are the permeability and permittivity of the negative refraction imaging structure, respectively, and μ₁ and ε_{⊥} are the permeability and permittivity of the pattern input layers, respectively) to reduce reflection and thus increase efficiency of coupling the light field carrying information of mask to the negative refraction imaging structure. The pattern input layers could reduce the adverse effect of TE component passing through the mask on lithography images quality.

The negative imaging refraction structure further comprises imaging output layers on opposite sides, and the imaging output layers are configured to reduce the difference between effective refraction index of the negative refraction imaging structure and refraction index of an outer space wherein the projection gap is located. The imaging output layers are used to improve the coupling efficiency of the mask pattern light field from the negative refraction imaging structure into air, immersion liquid, and photoresist. The mechanism is to select a suitable material thickness and suitable permittivity to reduce the difference between effective refraction index of the negative refraction imaging structure and refraction index of the outer space, so as to increase the transmission and output efficiency of the imaging light field.

A protective layer is further provided on the imaging output layers to protect the imaging output layers. It is required that a material of the protective layer is dense, chemically stable, and good in adhesion, which may effectively prevent oxidation and deliquescence of various materials in the negative refraction imaging structure and the imaging output layers without affecting the imaging lithographic effect.

A protective pane is further provided on the protective layer to surround the protective layer, so that the negative refraction imaging structure is spaced apart from the photoresist. The protective pane surrounds the pattern region and has a suitable height and width. The protective pane is used to prevent pattern region of lithographic lens from being damaged by contact during the lithographic processing. The protective pane has a height less than a working distance from a lower surface of the lithographic lens to upper surface of photoresist, has a suitable width a certain mechanical strength and good adhesion as a whole, and is easy to process. A composition material of the protective pane comprises, but not limited to, SiO₂, Si, etc.

The mask pattern is defense lines arranged in the same direction, and the polarization state of illumination light field perpendicular to the lines direction. The negative refraction imaging method and equipment may realize imaging with a 1:1 magnification, or achieve imaging with a reduced magnification by designing a curved negative refraction imaging structure. A demagnification ratio may be up to 2-10 times.

Since the negative refraction imaging has the non-optical axis imaging feature, it is easy to realize large-area high-resolution optical lithography. In practical cases, the imaging field is limited by control accuracy of the surface shape of the negative refraction imaging lens.

FIG. 5 illustrates a schematic diagram of a curved negative refraction imaging structure. As shown in FIG. 5, a mask (2), a negative refraction imaging structure (3), photoresist (7), and an imaging device substrate (8) each have a curved surface. When an illumination light (1) is incident, a transmission light wave (6) passing through the mask (2) is transmitted in a negative refraction manner along a radial direction of the curved surface, and then is focused and imaged on the photoresist (7) to realize high-resolution imaging with a reduced magnification.

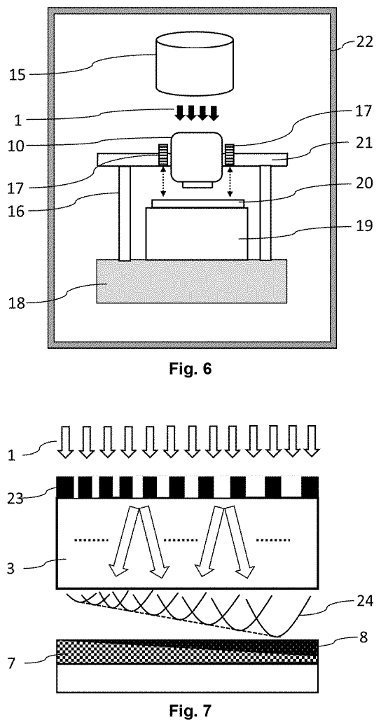

FIG. 6 illustrates a specific structural diagram of the negative refraction imaging lithographic equipment (200) shown in FIG. 2. As shown in FIG. 6, the negative refraction imaging lithographic equipment comprises an imaging lithographic lens (10), an exposure source (15), a substrate leveling and gap control system (16), a working distance detection system (17), a vibration isolation platform (18), a stage (19), an imaging substrate (20), an alignment and positioning system (21), and a clean box or vacuum box (22), etc.

Specifically, the negative refraction lithographic equipment may comprise a light source and illumination system, an imaging lithographic lens, a substrate leveling system, a working distance detection and control system, an alignment and positioning system, an air dust monitoring and purification system, etc. The wavelength of exposure source may cover deep ultraviolet to visible bands, comprising, but not limited to, an i-line 365 nm of a mercury lamp, g-lines 436 nm, 248 nm, 193 nm, 157 nm, etc.. The illumination system may adopt vertical illumination, off-axis illumination etc., or an arrayed light modulator may be introduced into the illumination system to achieve dynamic adjustment of parameters such as a direction, polarization, amplitude etc. The leveling methods comprise, but not limited to, self-collimation leveling, three-point leveling, laser interference leveling, moire fringe leveling etc. The methods used by the working distance detection system comprise, but not limited to, a white light interference method, an interference spatial phase method, etc. The lithographic equipment may further comprise an air purification system, comprising, but not limited to, a vacuum cavity prepared for purifying and circulating air etc.

FIG. 7 illustrates a schematic diagram of grayscale lithography. For different step structures, grayscale masks (23) with different critical dimensions are designed. An illumination light beam (1) forms a non-uniform imaging light field (24) through the grayscale mask (23) and a negative refraction imaging structure (3), and is used to expose different depths of photoresist (7) to obtain grayscale-exposured photoresist (8) which could removed by development to realize fabrication of a stepped or even continuous surface shape.

The negative refraction imaging structure has a stepped and continuous surface shape pattern lithography capability, and even a multilayered structure overlay lithography capability. Mask pattern with different duty ratios are used to form different exposure intensities in different regions of the photoresist, so as to obtain a multi-step and continuous surface structure pattern. The material of the photoresist layer comprises any kind of photoresist, a refraction index-modulation optically material or an absorption modulation optically material. The photoresist used may be replaced with other photosensitive materials, comprising, but not limited to, a refraction index modulation optically material and an absorption modulation optically material. Micro-nano structures, for example, refraction index modulated optical waveguide gratings etc., in a form of non-geometric topography are realized by necessary post-processing.

A mask fabrication method for the negative refraction imaging lithography comprise a stepping method or a scanning method. The negative refraction imaging lithographic method and equipment have a binary structure pattern, a stepped and continuous surface shape structure pattern lithography capability, and a multilayered pattern structure overlay lithography capability. Mask pattern is optimized to ensure nearly same image intensity for various parts of the pattern. For different step structures, a design of mask structure with different critical dimensions may be optimized. A difference between pattern imaging intensities in regions with different step heights is generated due to a difference between negative refraction imaging optical transfer functions. Pattern structures of the photoresist at different heights are obtained after the photoresist is developed, and a multi-step pattern is further obtained by etching transfer. Continuous surface shape structure lithography could be approximated and realized by increasing a number of steps. By using alignment marks of the negative refraction imaging lens, lithographic processing and etching transfer are performed on patterns of different layers many times, to ensure correct positions between the respective pattern layers, so as to realize multilayered pattern structure processing.

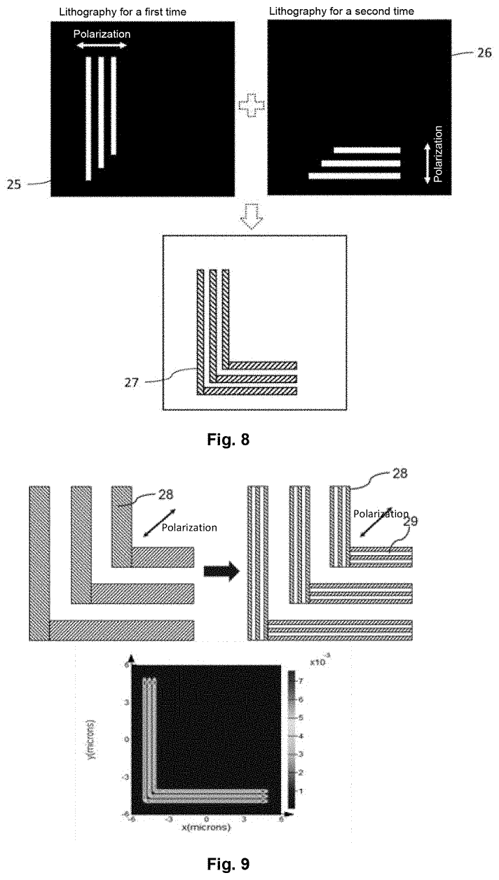

FIG. 8 illustrates a schematic diagram of two-dimensional pattern imaging lithography implemented by using the negative refraction imaging lithographic method and equipment according to an embodiment of the present disclosure. As shown in FIG. 8, a mask (25) is used for first time imaging lithography to obtain a vertical portion of a two-dimensional pattern (27), and then another mask 26 is used for second time imaging lithography to obtain a horizontal portion. Stacking and developing may be performed after the imaging lithography is performed twice to obtain a high-resolution two-dimensional pattern (27).

FIG. 9 illustrates schematic diagram of two-dimensional pattern imaging lithography implemented by using the negative refraction imaging lithographic method and equipment according to an another embodiment of the present disclosure. As shown in FIG. 9, a one-dimensional grating correction pattern (29) is introduced into a two-dimensional polyline mask pattern (28). Simulation results show that two-dimensional line pattern lithography may be achieved under a single imaging exposure condition.

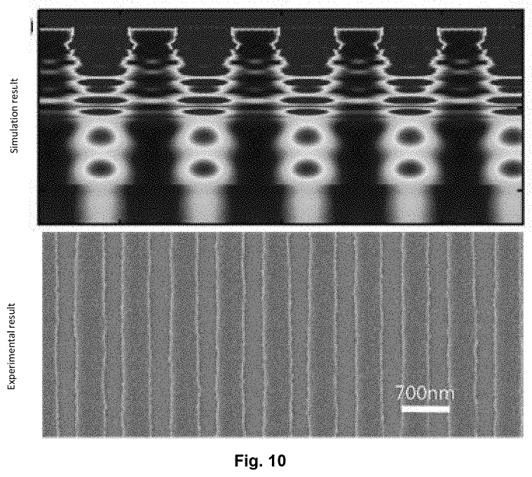

Specific operations of the negative refraction imaging lithographic method and equipment according to the present disclosure will be described in detail below with reference to FIGS. 1 to 6. The simulation and experimental results are as shown in FIG. 10. Firstly, a Cr mask having a thickness of 60 nm, a period of 700 nm, and a duty ratio of 0.5 is prepared on a quartz substrate. A organic glass PMMA having a thickness of 50 nm is spin-coated on the obtained Cr mask as a mask planarization layer. Eight Ag film layers and 7 TiO₂ film layers are alternately sputtered on the obtained structure, wherein each film layer has a thickness of 30 nm, and a TiO₂ film having a thickness of 5 nm continues to be sputtered on a surface of an outermost Ag film to prevent oxidation and deliquescence of the Ag film. A ultraviolet photoresist AR3170 having a thickness of 100 nm is spin-coated on a surface of a quartz substrate. The above substrates are fixed on two stages of a precise exposure gap control mechanism respectively, wherein quartz surfaces of the two substrates are in contact with the stages. The precise gap control mechanism—is controlled so that a gap between the two substrates is maintained to be about 400 nm. TM-polarized ultraviolet light having a central wavelength of 365 nm and a light intensity of 1 mW/m² is used for exposure from one side of the Cr mask for about 500 s to cause the photoresist on the quartz substrate to be sensitized. The photoresist-coated quartz substrate is removed from the stages of the precise gap control mechanism. The obtained quartz substrate is placed into an AZ300 developer for development for about 10 s to 15 s, and the developed substrate is dried. A pattern of dense lines is obtained on the photoresist with a period of 700 nm and a line width of 350 nm.

Compared with conventional projection lithographic lens, dozens of lenses with a nano-precision in surface shape and position are not required in the negative refraction imaging lithographic method and equipment according to the embodiments of the present disclosure, fabrication could be performed by integrated processing methods such as film deposition and electron beams etc., and thereby lens development costs may be drastically reduced. At the same time, the method has the characteristics of non-optical axis imaging, and the entire negative refraction imaging structure has spatial translational symmetry, and thus could realize large-area imaging without stitching. In consideration of surface shape processing accuracy and an element size of planar elements at present, an actual field of view of the lithographic imaging may be up to 100 mm² or more. Due to the physical isolation between the substrate and the mask, this method may implement operations such as high-precision alignment, positioning, and overlay processing of multilayered nano-structures etc. Based on the negative-refraction imaging lithographic structure, the present disclosure may realize high-resolution grayscale lithography for processing of a multi-step or continuous surface shape.

Although the present disclosure has been particularly shown and described with reference to typical embodiments thereof, it will be understood by those of ordinary skill in the art that various changes may be made to these embodiments in form and detail without departing from the spirit and scope of the present disclosure as defined by the appended claims.

1.-35. (canceled)

36. A negative refraction imaging lithographic method, comprising:
coating photoresist on a device substrate;
fabricating a negative refraction imaging structure on a mask, wherein the negative refraction imaging structure exhibits a negative refraction in response to beam emitted by an exposure source, that is, a refraction beam and an incidence beam are on the same side of the normal of imaging structure plane;
wherein the negative refraction imaging structure comprises a multilayered negative refraction imaging structure and a complex negative refraction imaging structure, and different negative refraction imaging structures are configured to achieve different effective refraction indexes and have different optical transfer functions,
wherein the negative refraction imaging structure comprises planar and curved imaging structures in a geometric form, wherein the planar negative refraction imaging structure is configured to achieve 1:1 imaging lithography, and the curved one is configured to achieve demagnification imaging lithography of 2 to 10 times, the negative refraction imaging structure has a pattern input layer and an imaging output layer on opposite sides, respectively, wherein the pattern input layer is configured to planarize the mask pattern, and increase coupling efficiency of light field carrying mask pattern information to the negative refraction imaging structure, and the imaging output layer is configured to increase transmission efficiency of imaging light field from negative refraction imaging structure to exposure gap;
wherein the mask comprises a mask substrate and a mask pattern layer, and the geometric form comprises a planar mask and a curved mask, on which the planar and curved negative refraction imaging structures are fabricated; and
keeping a definite projection gap between the negative refraction imaging structure and the device substrate;
the light emitted from exposure source projects on the photoresist for exposure through the mask, the pattern input layer, the negative refraction imaging structure, the imaging output layer, and the projection gap sequentially.

37. The negative refraction imaging lithographic method according to claim 36, wherein the negative refraction imaging structure exhibiting the negative refraction has a certain focal depth range in actual lithography, wherein this range is determined by a minimum image distance and a maximum image distance:
a relationship between minimum image distance and the parameters of the negative refraction imaging structure is:
$${d}_{i \_ min} = \frac{2}{3} ( L \sqrt{\frac{ɛ \text{?} ( {n}_{3}^{2} - 0.75 {n}_{1}^{2} )}{{ɛ}_{⊥} \text{?} ( {ɛ}_{⊥} - 0.75 {n}_{1}^{2} )}} - \frac{2 {d}_{s}}{{n}_{1}} \sqrt{{n}_{3}^{2} - 0.75 {n}_{1}^{2}} ) , \\ \text{?} \text{indicates text missing or illegible when filed} \qquad ( 1 )$$
and
a relationship between maximum image distance and the parameters of the negative refraction imaging structure is:
$${d}_{i \_ m ax} = ( \frac{L}{\sqrt{{ɛ}_{⊥}^{2} / ( {n}_{1}^{2} \cdot {\partial }_{‖} )}} - {d}_{s} ) \cdot \frac{{n}_{3}}{{n}_{1}} , \qquad ( 2 )$$
where dᵢ is image distance, dₛ is object distance, L is thickness of the negative refraction imaging structure, n_{⊥} is a refraction index of incident space, n_{g} is refraction index of exit space, ε_{∥} is the lateral component of effective permittivity of the negative refraction imaging structure, which is ε_{//}=f·ε_{d}+(1−f)·εₘ, and ε_{⊥} is a longitudinal component of effective permittivity, which is ε_{⊥}=ε_{d}·εₘ/[f·εₘ+(1−f)·ε_{d}], wherein ε_{//}>0 and ε_{⊥}<0, so that the multilayered structure exhibits optical negative refraction. where ε_{d} and εₘ are permittivities of dielectric and metal layer, respectively, f=d_{d}/(d_{d}+dₘ) is a thickness duty ratio of a dielectric layer, where d_{d} and dₘ are thicknesses of dielectric layer and metal layer, respectively.

38. The negative refraction imaging lithographic method according to claim 36, wherein the multilayered negative refraction imaging structure is composed by alternately stacking two or more kinds of material layers with different permittivities, and for the multilayer structure only composed of metal and dielectric layers, the corresponding thicknesses satisfy formula (3):
−(ε^{m}·d^{d})/ε^{d}<d^{m}<−(ε_{d}·d_{d})/εₘ(ε_{d}>0,εₘ<0) (3)
wherein the real part of the permittivity of at least one kind of materials in negative refraction imaging structure is negative, and the material comprises gold, silver, and aluminum.

39. The negative refraction imaging lithographic method according to claim 36, wherein the multilayers are, under the condition of negative refraction, a periodical alternant structure, or an aperiodic structure obtained by an optimization algorithm to improve resolution, focal depth and utilization efficiency for energy of the negative refraction imaging.

40. The negative refraction imaging lithographic method according to claim 36, wherein the complex negative refraction imaging structure comprises a hole-array multilayered negative refraction imaging structure and a three-dimensional negative refraction imaging structure;
wherein a two-dimensional hole-array structure is introduced into the multilayered negative refraction imaging structure exhibiting optical negative refraction to modulate effective permittivity and loss to realize negative refraction imaging, so as to form the hole-array multilayered negative refraction imaging structure.
wherein the three-dimensional negative refraction imaging structure is an imaging structure using a multilayered negative refraction imaging structure having a negative effective refraction index as a unit and having a variable effective negative refraction index distribution in the light transmission direction, and has an ability to achieve any effective negative refraction index and optical transfer function.

41. The negative refraction imaging lithographic method according to claim 36, wherein the wavelength of exposure source covers deep ultraviolet to visible light bands, comprising, but not limited to, i-line 365 nm of a mercury lamp, g-lines 436 nm, 248 nm, 193 nm, 157 nm, etc.

42. The negative refraction imaging lithographic method according to claim 36, wherein for a given mask with dense lines, there is an optimal illumination incident angle, which is the angle between incident beam and the normal of negative refractive imaging structure surface, so that the focal length and contrast of the fringe field in the corresponding focal plane reach maximum values, and an optimal incidence angle satisfies formula (4)
$${θ}_{opt} = arcsin ( \frac{λ}{2 {n}_{l} Λ} ) \qquad ( 4 )$$
wherein θₒₚₜ is the optimal illumination incident angle, nᵢ is refraction index of an incident space, and λ and A are wavelength of exposure source and period of dense line, respectively.

43. The negative refraction imaging lithographic method according to claim 36, wherein the pattern input layers planarize the mask pattern, and the composition material is transparent, and has a high refraction index and a low loss, a thickness of the pattern input layer is optimized to be matched with geometrical parameters of the negative refraction imaging structure, and the permittivity and permeability of the pattern input layer are adjusted to achieve impedance matching between the pattern input layer and the negative refraction imaging structure to reduce reflection and increase the coupling efficiency of the light field carrying the mask pattern information to the negative refraction imaging structure.

44. The negative refraction imaging lithographic method according to claim 36, wherein the negative refraction imaging structure further comprises imaging output layers on opposite sides, and the imaging output layers are configured to reduce a difference between the effective refraction index of the negative refraction imaging structure and refraction index of an outer space, so as to increase the transmission efficiency of the imaging light field to outer space,
a protective layer is further provided on the imaging output layers to protect the imaging output layers, and a protective pane is further provided on the protective layer to surround the protective layer, so that the negative refraction imaging structure is spaced apart from the photoresist, and
liquid is filled between the protective pane and the device substrate to increase an effective numerical aperture of the negative refraction imaging structure and thus improve resolution and focal depth of the negative refraction imaging lithography.

45. The negative refraction imaging lithographic method according to claim 36, wherein the mask pattern comprises one-dimensional line patterns arranged in the same direction and one-dimensional line patterns arranged in different directions, and the electric field of the illumination light is polarized perpendicularly to lines direction,
the pattern of the mask further comprises a two-dimensional complex pattern which could be decomposed into one-dimensional patterns in different directions, and the negative refraction imaging lithographic method has an ability to achieve high-resolution two-dimensional complex patterns by stitching two or more exposure results of different one-dimensional mask patterns in different directions under polarized illumination in the respective directions, and
a sub-wavelength grating structure is introduced to two-dimensional pattern in mask, so that the TM polarized component is projected on two orthogonal direction under the definite polarization direction of incident light, and two-dimensional pattern lithography could be achieved in once exposure.

46. The negative refraction imaging lithographic method according to claim 36, wherein the pattern of the mask further comprises grayscale pattern, by employing the features of different transmission of negative refraction imaging structure for pattern with different duty cycle in mask, which leads to different exposure intensities in different regions of photoresist, so that a stepped and continuous surface structure pattern lithography are realized.

47. A negative refraction imaging lithographic equipment, comprising:
an exposure source, an illumination system, an imaging lithography objective lens, a substrate leveling system, a working distance detection and control system, an alignment and positioning system, and an air dust monitoring and purification system, etc.
wherein the imaging lithography objective lens is configured to have a mask and a negative refraction imaging structure;
wherein the negative refraction imaging structure exhibits optical negative refraction in response to beam emitted by exposure source;
wherein the negative refraction imaging structure comprises multilayered negative refraction imaging structure having metal and dielectric layers stacked therein and a complex negative refraction imaging structure, and different negative refraction imaging structures are configured to achieve different effective refraction indexes and have different optical transfer functions;
wherein the negative refraction imaging structure comprises planar and curved negative refraction imaging structures in a geometric form, wherein the planar negative refraction imaging structure is configured to achieve 1:1 imaging lithography, and the curved negative refraction imaging structure is configured to achieve demagnification imaging lithography;
wherein two sides of negative refraction imaging structure are a pattern input layer and an imaging output layer on opposite sides, wherein the pattern input layer is configured to planarize mask pattern, and increase coupling efficiency of light field carrying mask pattern information to the negative refraction imaging structure, and the imaging output layer is configured to increase transmission efficiency of imaging light field from negative refraction imaging structure to outer space;
wherein the mask comprises planar mask and curved mask, which correspond to the planar and curved negative refraction imaging structures;
wherein the working distance detection and control system manages the imaging lithography objective lens above the device substrate at a definite projection distance for exposure; and
wherein light emitted by exposure source passes through the mask, the negative refraction imaging structure, the projection gap and is sequentially projected onto the photoresist.

48. The negative refraction imaging lithographic equipment according to claim 47, wherein the illumination system adopts vertical illumination or off-axis illumination, or has an arrayed light modulator introduced therein to realize dynamic adjustment and control of the direction, polarization and amplitude of illumination beam.

49. The negative refraction imaging lithographic equipment according to claim 47, wherein the leveling method used comprises, but not limited to, auto-collimation leveling, three-point leveling, laser interference leveling, and Moiré fringe leveling, and the method adopted by the working distance detection system comprises, but not limited to, white light interference method, and interference space phase method.

50. The negative refraction imaging lithographic equipment according to claim 47, wherein the substrate leveling apparatus, the working distance detection and control system, the alignment and positioning system enable the negative refraction imaging lithography to have the multilayered pattern structure overlay ability and two-dimensional pattern stitching lithography ability.
